(19) United States
(12) Patent Application Publication
(10) Pub. No.: US 2009/0104804 A1
(43) Pub. Date: Apr. 23, 2009

(54) LED METAL STRIP FLEXIBLE INTERCONNECTION

(76) Inventor: Jeff Lin, Novi, MI (US)

Correspondence Address: FRASER CLEMENS MARTIN & MILLER LLC, 28366 KENSINGTON LANE, PERRYSBURG, OH, 43551, US

(21) Appl. No.: 11/876,838

(22) Filed: Oct. 23, 2007

(51) Int. Cl. H01R 4/58; H05K 3/10

(52) U.S. Cl. 439/211; 29/846

(57) ABSTRACT

An LED interconnection apparatus and a method of electrical connection for an array of LEDs are disclosed, the LED interconnection apparatus including a back plate substrate having a plurality of adaptable through-holes formed therein and a flexible conductive pattern disposed adjacent the back plate substrate, wherein the adaptable through-holes of the back plate substrate facilitate selective access to the flexible conductive pattern to provide a simple, adaptable, and standardized method of electrical communication for an array of LEDs.

### FIELD OF THE INVENTION

The present invention relates to a light source assembly and more particularly to a light emitting diode interconnection apparatus and a method of electrical connection for an array of light emitting diodes.

### BACKGROUND OF THE INVENTION

Light emitting diodes (LED) are currently used in various illumination capacities, such as, advertisement and signaling, for example. A plurality of LEDs may be arranged in various lighting patterns to produce a desired lighting effect. The plurality of LEDs is typical coupled to a substrate to form a light source assembly. Currently, both rigid and flexible substrates are used for support and electrical communication between a power source and the plurality of LEDs.

The light source assembly includes a desired electrical circuitry pattern to regulate a power and a current routing of the light source assembly. The electrical circuitry pattern also provides electrical communication between the LEDs. The use of pre-formed circuitry, such as a printed wiring board, is efficient where the light source assembly is being mass produced. Since mass production of a light source assembly typically requires a standardized circuitry pattern and connection pattern, tools and methods used in the mass production of a light source assembly may be adapted to efficiently produce a particular light source assembly. Where production of the light source assembly is on a small scale, the use of pre-formed circuitry can be costly. The constant adaptation of tools and methods of production for the manufacturing of various light source assemblies can be inefficient. Often, a light source assembly may require custom formed circuitry patterns and lighting arrangements for a particular application. Customization of each light source assembly is time intensive and costly.

It would be desirable to develop an LED interconnection apparatus and a method of electrical connection for an array of LEDs, wherein the method and apparatus provide a simple, flexible and standardized means of adaptable electrical communication between a power source and the array of LEDs.

### SUMMARY OF THE INVENTION

Concordant and consistent with the present invention, an LED interconnection apparatus and a method of electrical connection for an array of LEDs, wherein the method and apparatus provide a simple, flexible and standardized means of adaptable electrical communication between a power source and the array of LEDs, has surprisingly been discovered.

In one embodiment, the LED interconnection apparatus comprises a back plate substrate including a plurality of adaptable through-holes; and a flexible conductive pattern disposed adjacent the back plate substrate, wherein the adaptable through-holes of the back plate substrate facilitate selective access to the flexible conductive pattern.

In another embodiment, a back plate substrate including a plurality of adaptable through-holes; and an annular conductive strip pattern disposed adjacent the back plate substrate, wherein the adaptable through-holes of the back plate substrate allow selective access to the conductive strip.

Methods of electrical connection for an LED array are also disclosed.

In one embodiment, the method comprises the steps of providing a back plate substrate including a plurality of adaptable through-holes; providing a flexible conductive pattern disposed adjacent the back plate substrate, wherein the adaptable through-holes of the back plate substrate facilitate selective access to the flexible conductive pattern; forming the flexible conductive pattern using a first forming operation to conform to a shape of the back plate substrate; coupling the flexible conductive pattern to a first side of the back plate substrate; shaping a desired number of unformed connector terminals using a second forming operation to provide electrical interconnection; and severing a desired portion of the flexible conductive pattern using a secondary punching operation to create a desired circuitry pattern.

### BRIEF DESCRIPTION OF THE DRAWINGS

The above, as well as other advantages of the present invention, will become readily apparent to those skilled in the art from the following detailed description of the preferred embodiment when considered in the light of the accompanying drawings in which:

FIG. 1 is a front perspective view of an LED interconnection apparatus according to an embodiment of the present invention;

FIG. 2 is a rear perspective view of the LED interconnection apparatus according to the embodiment shown in FIG. 1; and

FIG. 3 is a front elevational view of a conductive strip pattern according to another embodiment of the present invention.

### DETAILED DESCRIPTION OF EXEMPLARY EMBODIMENTS OF THE INVENTION

The following detailed description and appended drawings describe and illustrate various embodiments of the invention. The description and drawings serve to enable one skilled in the art to make and use the invention, and are not intended to limit the scope of the invention in any manner. In respect of the methods disclosed, the steps presented are exemplary in nature, and thus, the order of the steps is not necessary or critical.

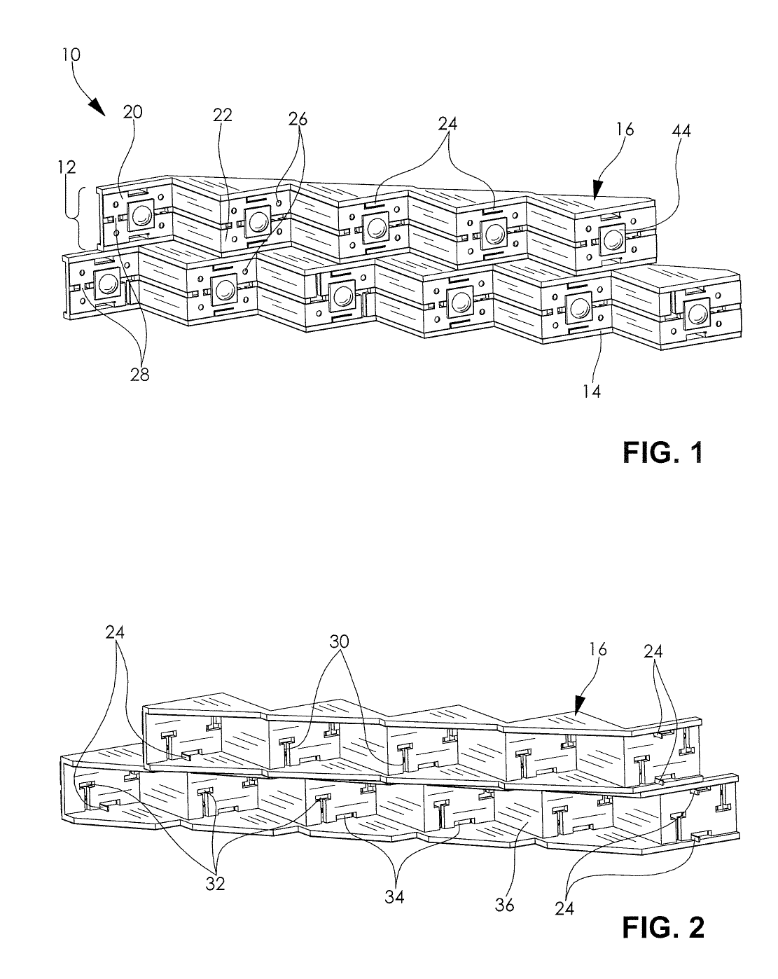

FIG. 1 illustrates an LED interconnection apparatus 10 according to an embodiment of the present invention. The LED interconnection apparatus 10 includes a flexible conductive pattern 12 coupled to a first side 14 of a back plate substrate 16.

As illustrated, the flexible conductive pattern 12 is a dual conductive strip pattern having a first conductive strip 20 and a second conductive strip 22. It is understood that the flexible conductive pattern 12 may be a single strip (not shown) or other pattern as desired. The flexible conductive pattern 12 includes a plurality of connector terminals 24, a coupling feature 26, and a plurality of strip separation tabs 28, disposed therein. The connector terminals 24 are formed in the flexible conductive pattern 12 and may be selectively bent to provide an interconnection between adjacent flexible conductive patterns 12. The coupling feature 26 may be any conventional coupling feature for coupling the flexible conductive pattern 12 and the back plate substrate 16 such as an aperture adapted for a heat staking operation, for example. As shown, the strip separation tabs are disposed between the first conductive strip 20 and the second conductive strip 22. The strip separation tabs 28 provide electrical communication between the first conductive strip 20 and the second conductive strip 22 of the flexible conductive pattern 12. The flexible conductive pattern 12 may be formed from any conventional conductive material such as a metal, for example. Any conventional means of preparing conductive frets can be used to produce the flexible conductive pattern 12 such as a stamping operation, for example. The flexible conductive pattern 12 may be formed into any conventional shape or pattern such as, a single segment element and a continuous strip, for example. Where the flexible conductive pattern 12 is a single segment element, the flexible conductive pattern 12 may be pre-formed using a first forming operation to conform to a shape of a fixed back plate substrate 16 design. If the flexible conductive pattern 12 is a continuous strip, the continuous strip may be post-formed using the first forming operation to conform to various shapes of back plate substrates 16.

As illustrated in FIG. 2, the back plate substrate 16 includes a plurality of punch out windows 30, a plurality of separation tab windows 32, and a plurality of terminal forming windows 34, collectively referred to as a plurality of adaptable through-holes. The adaptable through-holes 30, 32, 34 of the back plate substrate 16 provide access to portions of the flexible conductive pattern 12 from a second side 36 of the back plate substrate 16. Specifically, the adaptable through-holes 30, 32, 34 of the back plate substrate 16 are substantially aligned with a portion of the flexible conductive pattern 12. For example, the separation tab windows 32 of the back plate substrate 16 are aligned with the strip separation tabs 28 of the flexible conductive pattern 12; the terminal forming windows 34 of the back plate substrate 16 are aligned with the connector terminals 24; and the punch out windows 30 are aligned with a desired portion of the flexible conductive pattern 12 along a longitudinal axis thereof. The back plate substrate 16 is shown as having a stair step shape. It is understood that the back plate substrate 16 may have any desired shape and size.

In use, the flexible conductive pattern 12 is disposed adjacent the first side 14 of the back plate substrate 16. The flexible conductive pattern 12 is coupled to the back plate substrate 16 using any conventional means of coupling such as heat staking and snapping, for example. Once the flexible conductive pattern 12 is coupled to the back plate substrate 16, a second forming operation is used on the flexible conductive pattern 12 to shape a desired number of connector terminals 24. In the embodiment shown in FIG. 2, the unformed connector terminals 24 of the flexible conductive pattern 12 are selectively bent so that each of the bent connector terminals 24 protrude through one of the terminal forming windows 34 of the back plate substrate 16. The bent connector terminals 24 are coupled to the bent connector terminals 24 of an adjacent flexible conductive pattern to provide electrical communication between adjacent flexible conductive patterns 12. A punching operation is then used on the flexible conductive pattern 12 to selectively trim the portions of the flexible conductive pattern 12 through the punch out windows 30 and the separation tab windows 32 to form a desired circuitry pattern. Trimming the flexible conductive pattern 12 through the punch out windows 30 severs electrical communication along the longitudinal axis of the flexible conductive pattern 12. Trimming the flexible conductive pattern 12 through the separation tab window 32 severs electrical communication between the first conductive strip 20 and the second strip 22. The desired circuitry pattern may be any circuitry pattern such as series and parallel, for example. It is understood that the desired circuitry pattern may be formed by the punching operation before the flexible conductive pattern 12 is coupled to the back plate substrate 16. A plurality of LEDs 44 is coupled to the flexible conductive pattern 12 at a pre-determined location. The flexible conductive pattern 12 provides electrical communication between the plurality of LEDs 44 and a power source (not shown). It is understood that the LED interconnection apparatus 10 may also provide electrical communication between a plurality of flexible conductive patterns 12.

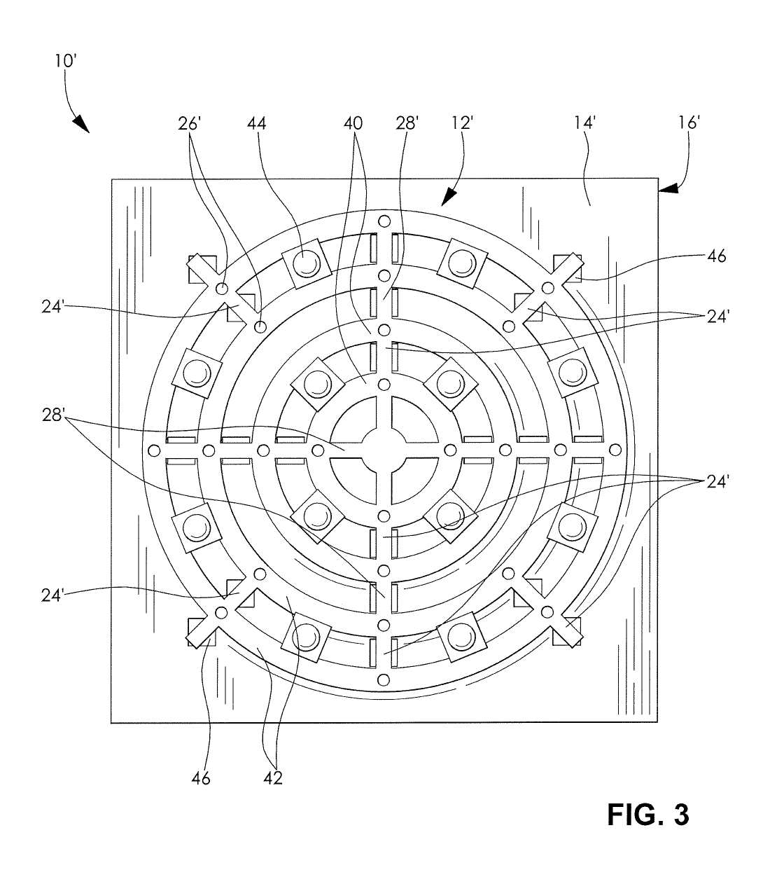

FIG. 3 shows an LED interconnection apparatus 10′ according to another embodiment of the invention. Structure repeated from the description of FIGS. 1 and 2 includes the same reference numeral and a prime (′) symbol. The LED interconnection apparatus 10′ includes a flexible conductive pattern 12′ and a back plate substrate 16′. In the embodiment shown, the flexible conductive pattern 12′ is an annular conductive strip pattern. The flexible conductive pattern 12′ includes a plurality of connector terminals 24′, a coupling feature 26′, and a plurality of separation tabs 28′, disposed therein. The connector terminals 24′ are formed in the flexible conductive pattern 12′ and may be selectively bent to provide an interconnection between adjacent flexible conductive patterns 12′. The coupling feature 26′ may be any conventional coupling feature for coupling the flexible conductive pattern 12′ and a back plate substrate 16′ such as an aperture adapted for a heat staking operation, for example. As shown, the strip separation tabs 28′ are disposed between an inner conductive strip 40 and an outer conductive strip 42. The strip separation tabs 28′ provide electrical communication between the inner conductive strip 40 and the outer conductive strip 42 of the flexible conductive pattern 12′. The flexible conductive pattern 12′ may be formed from any conventional conductive material such as a metal, for example. The flexible conductive pattern 12′ is produced using any conventional means of preparing metal frets such as a stamping operation, for example.

The back plate substrate 16′ shown includes a plurality of through-holes 46, the through-holes 46 adapted to provide selective access to the flexible conductive pattern 12′. Although the back plate substrate 16′ is shown as having a rectangular shape, it is understood that the back plate substrate 16′ may have any conventional shape and size.

In use, the flexible conductive pattern 12′ is disposed adjacent the first side 14′ of the back plate substrate 16′. The flexible conductive pattern 12′ is coupled to the back plate 16′ substrate using any conventional means of coupling such as heat staking and snapping, for example. Once the flexible conductive pattern 12′ is coupled to the back plate substrate 16′, the connector terminals 24′ are selectively shaped by a second forming operation to provide electrical communication between the connector terminals 24′ of adjacent flexible conductive patterns 12′. It is understood that the second forming operation may be used to shape a desired number of connector terminals 24′ before the flexible conductive pattern 12′ is coupled to the back plate substrate 16′. A punching operation is used on the flexible conductive pattern 12′ to selectively trim portions of the flexible conductive pattern 12′ to form a desired circuitry pattern. In the embodiment shown in FIG. 3, the strip separation tabs 28′ are punched, thereby separating an inner conductive strip 40 from an outer conductive strip 42 and creating the desired circuitry pattern. The desired circuitry pattern may be any circuitry pattern such as series and parallel, for example. It is understood that the desired circuitry pattern may be formed by the punching operation before the flexible conductive pattern 12′ is coupled to the back plate substrate 16′. A plurality of LEDs 44′ is coupled to the flexible conductive pattern 12′ to form a desired lighting pattern. The flexible conductive pattern 12′ provides electrical communication between the LEDs 44′ and a power source (not shown). It is understood that the flexible conductive pattern 12′ may also be adapted to provide electrical communication between a plurality of flexible conductive patterns 12′.

The LED interconnection apparatuses 10, 10′ provide a simplified, standardized, and adaptable means of electrical connection for arrays of LEDs 44, 44′. The back plate substrate 16, 16′, in cooperation with the flexible conductive pattern 12, 12′, facilitates an efficient assembly process for arrays of LEDs 44, 44′ and various lamp designs. The back plate substrate 16, 16′, in cooperation with the flexible conductive pattern 12, 12′, further provides an inexpensive and simplified method of circuitry formation and modification. The standardization of the flexible conductive pattern 12, 12′ allows the flexible conductive pattern 12, 12′ to be easily mass produced. The adaptable features of the flexible conductive pattern 12, 12′ and back plate substrate 16, 16′ provide easily customized circuitry patterns and connector terminals 24, 24′ for a variety of applications.

From the foregoing description, one ordinarily skilled in the art can easily ascertain the essential characteristics of this invention and, without departing from the spirit and scope thereof, make various changes and modifications to the invention to adapt it to various usages and conditions.

What is claimed is:

1. A method of electrical connection for an LED array, the method comprising the steps of:
providing a back plate substrate including a plurality of adaptable through-holes;
providing a flexible conductive pattern disposed adjacent the back plate substrate, wherein the adaptable through-holes of the back plate substrate facilitate selective access to the flexible conductive pattern;
forming the flexible conductive pattern using a first forming operation to conform to a shape of the back plate substrate;
coupling the flexible conductive pattern to a first side of the back plate substrate;
shaping a desired number of unformed connector terminals using a second forming operation to provide electrical interconnection; and
severing a desired portion of the flexible conductive pattern using a secondary punching operation to create a desired circuitry pattern.

2. The method according to claim 1, wherein the flexible conductive pattern includes a plurality of connector terminals, a coupling feature, and a plurality of strip separation tabs disposed therein.

3. The method according to claim 2, wherein the adaptable through-holes facilitate severing a desired number of strip separation tabs to prevent electrical communication between a first conductive strip and a second conductive strip of the flexible conductive pattern.

4. The method according to claim 1, wherein the adaptable through-holes of the back plate substrate align with a desired portion of the flexible conductive pattern.

5. The method according to claim 1, wherein the second forming operation is a selective bending of the connector terminals to provide electrical communication between adjacent flexible conductive patterns.

6. The method according to claim 1, wherein the adaptable through-holes facilitate severing a desired portion of the flexible conductive pattern along a longitudinal axis thereof to create the desired circuitry pattern.

7. An LED interconnection apparatus comprising:
a back plate substrate including a plurality of adaptable through-holes; and
a flexible conductive pattern disposed adjacent the back plate substrate, wherein the adaptable through-holes of the back plate substrate facilitate selective access to the flexible conductive pattern.

8. The LED interconnection apparatus according to claim 7, wherein the flexible conductive pattern includes a plurality of connector terminals, a coupling feature, and a plurality of strip separation tabs disposed therein.

9. The method according to claim 8, wherein the adaptable through-holes facilitate severing a desired number of strip separation tabs to prevent electrical communication between a first conductive strip and a second conductive strip of the flexible conductive pattern.

10. The LED interconnection apparatus according to claim 7, wherein the adaptable through-holes of the back plate substrate are aligned with a desired portion of the flexible conductive pattern.

11. The LED interconnection apparatus according to claim 8, wherein the connector terminals are adapted to provide electrical communication between a plurality of flexible conductive patterns.

12. The method according to claim 7, wherein the adaptable through-holes facilitate severing a desired portion of the flexible conductive pattern along a longitudinal axis thereof to create a desired circuitry pattern.

13. The LED interconnection apparatus according to claim 7, wherein the flexible conductive pattern is a dual conductive strip.

14. The LED interconnection apparatus according to claim 7, wherein the flexible conductive pattern is an annular conductive strip pattern.

15. An LED interconnection apparatus comprising:
a back plate substrate including a plurality of adaptable through-holes; and
an annular conductive strip pattern disposed adjacent the back plate substrate, wherein the adaptable through-holes of the back plate substrate allow selective access to the conductive strip.

16. The LED interconnection apparatus according to claim 15, wherein the flexible conductive pattern includes a plurality of connector terminals, a coupling feature, and a plurality of strip separation tabs disposed therein.

17. The LED interconnection apparatus according to claim 15, wherein the through-holes of the back plate substrate align with a desired portion of the flexible conductive pattern.

18. The LED interconnection apparatus according to claim 15, wherein the connector terminals are adapted to provide electrical communication between a plurality of flexible conductive patterns.

19. The, LED interconnection apparatus according to claim 15, wherein a punching operation on the annular conductive strip pattern creates a desired circuitry pattern.
